(19) United States
(12) Patent Application Publication
(10) Pub. No.: US 2015/0207050 A1
(43) Pub. Date: Jul. 23, 2015

(54) SEMICONDUCTOR PACKAGE AND MANUFACTURING METHOD THEREOF

(71) Applicants: Kenji Tsukada, Toyota-shi (JP); Masatoshi Fujita, Anjo-shi (JP); Masato Suzuki, Chiryu-shi (JP); Akihiro Kawajiri, Chiryu-shi (JP); Kazuhiro Sugiyama, Minokamo-shi (JP); Yoshitaka Hashimoto, Kariya-shi (JP)

(72) Inventors: Kenji Tsukada, Toyota-shi (JP); Masatoshi Fujita, Anjo-shi (JP); Masato Suzuki, Chiryu-shi (JP); Akihiro Kawajiri, Chiryu-shi (JP); Kazuhiro Sugiyama, Minokamo-shi (JP); Yoshitaka Hashimoto, Kariya-shi (JP)

(73) Assignee: FUJI MACHINE MFG CO., LTD., Aichi (JP)

(21) Appl. No.: 14/399,710

(22) PCT Filed: May 8, 2012
(86) PCT No.: PCT/JP12/61720

§ 371 Date: Mar. 13, 2015

(51) Int. Cl. H01L 33/62; H01L 33/48

(52) U.S. Cl. CPC H01L 33/62; H01L 33/486; H01L 2933/0033; H01L 2933/0066

(57) ABSTRACT

For a semiconductor package mounted on a mounting member with wiring which connects an electrode on the upper surface of an LED device (semiconductor device) and an electrode at the mounting member side formed by a droplet discharge method or printing method, a stress relaxation film to reduce stresses applied to the wiring due to the difference in expansion/contraction between a land at the level difference sections and the wiring is formed at least at the level difference sections in the land which forms wiring, and the wiring is formed by a droplet discharge method or printing method on the stress relaxation film. The stress relaxation film may be formed of an insulating material for which the difference of the linear expansion coefficient from wiring is as small as possible and for which the Young's modulus is as large as possible.

### TECHNICAL FIELD

The present invention relates to a semiconductor package and a manufacturing method thereof which have improved reliability of wiring between the electrode of a semiconductor device mounted on a mounting member and the electrode of the mounting member.

### BACKGROUND ART

Conventionally, in the mounting process of semiconductor devices, after a semiconductor device is die bonded to a mounting member (circuit board, lead frame, and so on), wiring the electrode of the semiconductor device side and the electrode of the mounting member side by wire bonding is typical.

However, as disclosed in patent literature 1 (Japanese Patent Publication Number 3992038), because there is a possibility that defects may occur due to mechanical stress when wire bonding is performed, with the aim to achieve a mounting structure with high connection reliability as an alternative to wire bonding at low cost, it has been proposed to form wiring by discharging conductive ink using a droplet discharge method such as ink jetting along a wiring path which connects an electrode of the upper surface of a semiconductor device and an electrode of a wiring board after forming a resin slope which connects the upper surface of a semiconductor device and the surface of a wiring board at an inclined surface by discharging liquid resin material with a dispenser around a semiconductor device mounted on a wiring board and hardening it.

Alternatively, as disclosed in patent literature 2 (Japanese Unexamined Patent Application Publication Number 2005-50911), it has been proposed, by mounting a semiconductor device inside an element mounting cavity formed in a mounting member, along with making the height of an electrode of the upper surface of a semiconductor device and an electrode provided on the outer side of an element mounting cavity of the mounting member the same and planarizing a wiring path between an electrode of the upper surface of a semiconductor device and an electrode of a mounting member by embedding an insulator in a gap (groove) between the inside surface of an element mounting cavity of the mounting member and the outside surface of the semiconductor device, to form wiring by discharging conductive ink using a droplet discharge method such as ink jetting along the wiring path.

### CITATION LIST

### Patent Literature

Patent Literature 1: Japanese Patent Publication Number 3992038

Patent Literature 2: Japanese Unexamined Patent Application Publication Number 2005-50911

### SUMMARY OF INVENTION

### Problem to be Solved by the Invention

With the wiring structures in patent literature 1 and 2 above, it is required to form wiring which connects an electrode of the upper surface of a semiconductor device and an element of a mounting member across multiple materials (electrode of a semiconductor chip, semiconductor chip, sloped resin/embedded resin, mounting member, electrode of a mounting member, and so on) which are located in a wiring path. Although the large level differences which arise in the material boundary sections in a wiring path are attempted to be filled with a resin slope or embedded resin, in fact, it is difficult to make level differences in the material boundary sections completely zero and tiny level differences still remain. Also, there are tiny level differences between the upper surface of a semiconductor chip and an electrode, or between the upper surface of a mounting member and an electrode. A droplet discharge method or printing method has advantages that wiring can be drawn even if there are tiny level differences in a wiring path, however, because wiring is dried/baked at a specified baking temperature after drawing, wiring is expanded/contracted by heating/heat dissipation during drying/baking, or wiring is expanded/contracted through the temperature cycle when they are used with power being supplied after manufacturing. Here, stresses are intensively applied to the angled sections of level difference sections of the wiring by the difference in the expansion/contraction between the wiring and the land, so the wiring is sometimes disconnected at the angled sections of the level difference sections.

Therefore, the object of the present invention is to provide a semiconductor package and manufacturing method thereof which can prevent to a great extent disconnections at the angled sections of level difference sections due to repeated expansion/contraction of wiring which connects an electrode of a semiconductor device and an electrode of the mounting member side.

### Means for Solving the Problem

To solve the above problem, the present invention is a semiconductor package with a semiconductor device mounted on a mounting member which is formed with wiring connecting an electrode of the semiconductor side and an electrode of the mounting member side and a manufacturing method thereof, wherein a stress relaxation film to reduce stresses applied to the wiring due to the difference in expansion/contraction between the level difference sections and the wiring is formed at least at the level difference sections among the sections which form the wiring, and the wiring is formed on the stress relaxation film by any one of a droplet discharge method, printing method, plating, PVD, mounting conductive member, and so on. By doing this, because stresses applied to level difference sections of wiring due to the difference in expansion/contraction between the level difference sections and the wiring can be reduced by a stress relaxation film, it is possible to a great extent to prevent wiring formed by a droplet discharge method or printing method from being disconnected at angled sections of level difference sections by repeated expansion/contraction.

Also, for the present invention, it is acceptable to form a stress relaxation film to reduce stresses applied to the wiring due to the difference in expansion/contraction between the level difference sections and the wiring at least at the upper surface and/or the side surface of the level difference sections in the wiring. In this way also, because stresses applied to level difference sections in wiring by difference in expansion/contraction between a land and wiring at the level difference sections can be reduced by a stress relaxation film formed at the upper surface and/or the side surface, it is possible to a great extent to prevent wiring formed by a droplet discharge method or printing method from being disconnected at angled sections of level difference sections by repeated expansion/contraction.

In this case, it is acceptable for a stress relaxation film to be formed of a material for which the difference of the linear expansion coefficient from that of the wiring is equal to or smaller than a predetermined value (for example 40 ppm/degrees C. or less). That is, a stress relaxation film may be formed of a material for which the difference of the linear expansion coefficient from that of the wiring is small as possible. This is because the smaller the difference between the linear expansion coefficient of the stress relaxation film and the wiring becomes, the larger the stress relaxation effects of the stress relaxation film become.

Also, if a stress relaxation film is formed by a droplet discharge method or printing method, a stress relaxation film can be efficiently formed with the same level of positional accuracy as the wiring. In addition, it is also acceptable to connect an insulating film or solid insulation used as a stress relaxation film to a land or wiring.

### BRIEF DESCRIPTION OF DRAWINGS

[FIG. 1]

FIG. 1 is a cross section showing the structure of the LED package of embodiment 1 of the present invention.

[FIG. 2]

FIG. 2 is a top view of the LED package of embodiment 1.

[FIG. 3]

FIG. 3 is a cross section showing the structure of the LED package of embodiment 2.

[FIG. 4]

FIG. 4 is a cross section showing the structure of the LED package of embodiment 3.

[FIG. 5]

FIG. 5 is a cross section showing the structure of the LED package of embodiment 4.

[FIG. 6]

FIG. 6 is a top view of the LED package of embodiment 5.

### DESCRIPTION OF EMBODIMENTS

The following describes several specific embodiments for carrying out the present invention using an LED package.

### Embodiment 1

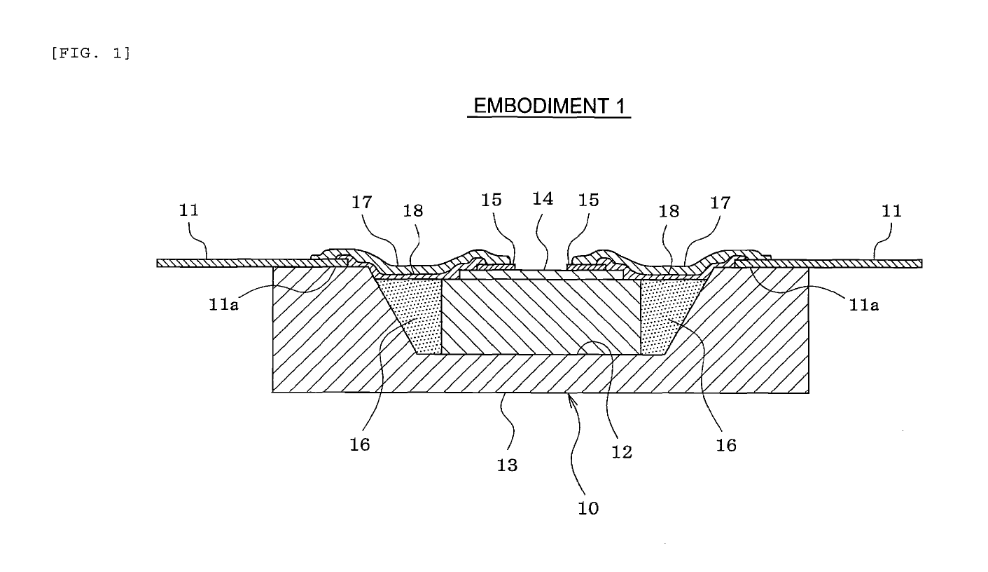

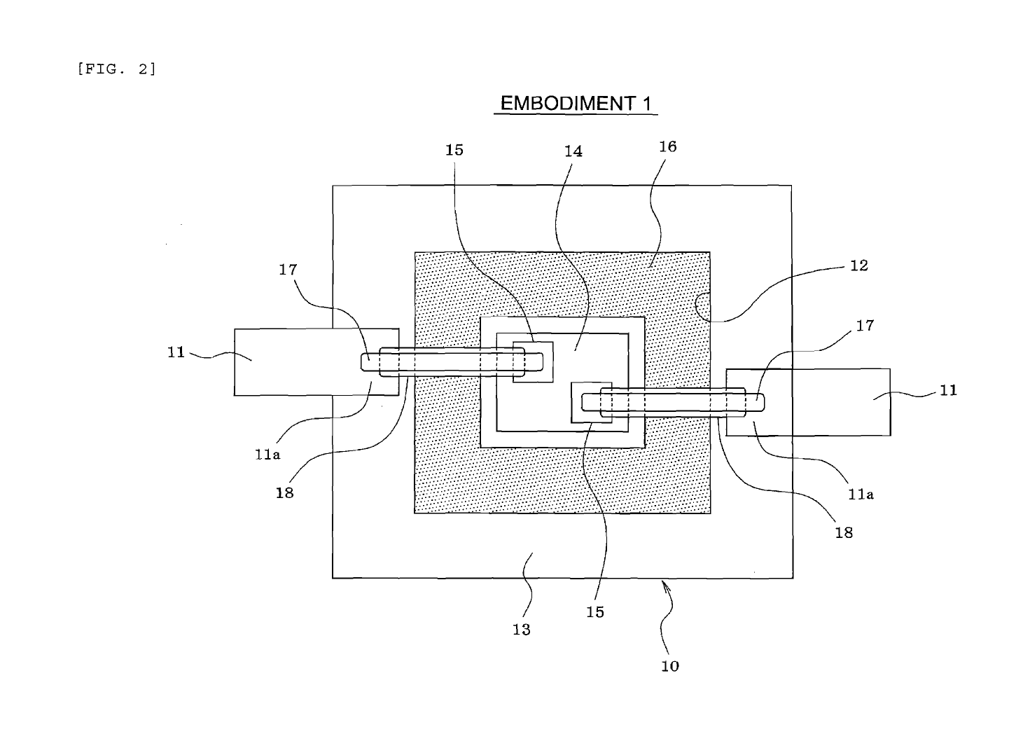

This describes embodiment 1 of the present invention based on FIG. 1 and FIG. 2. Mounting member 10 is comprised by forming package body 13 which has an element mounting cavity 12 in lead frame 11 with insulating resin. In the central part of the bottom of element mounting cavity 12 of this package body 13, LED device 14 (light-emitting element) which is a semiconductor device is die bonded (bonded). The depth (height) of element mounting cavity 12 is specified almost the same as the height of LED device 14, and electrode 15 on the upper surface of LED device 14 which has been mounted in element mounting cavity 12 is almost the same height as electrode 11a of lead frame 11 on the upper surface of package body 13.

Transparent embedded resin layer 16 is formed around LED device 14 in element mounting cavity 12 in package body 13 by filling transparent insulating resin therein using a droplet discharge method such as ink jetting or dispensing. By this, for the wiring path which connects electrode 15 on the upper surface of LED device 14 and electrode 11a on the upper surface of package body 13, level differences (unevenness) are smaller due to embedded resin layer 16 filled around LED device 14, and on the embedded resin layer 16, insulating stress relaxation film 18 which becomes a land of wiring 17 to be mentioned later is formed in a line shape or band shape across electrode 15 on the upper surface of LED device 14 and electrode 11a on the upper surface of package body 13.

This stress relaxation film 18 is formed of an insulating material for which the difference of the linear expansion coefficient from that of wiring 17 is equal to or smaller than a predetermined value A (for example 40 ppm/degrees C. or less) and for which the Young's modulus is equal to or larger than a predetermined value B (for example 2.8 GPa or larger), and more preferably with an insulating material for which the difference of the linear expansion coefficient from that of wiring 17 is as small as possible and for which the Young's modulus is as large as possible. With this method of forming stress relaxation film 18, the above insulating ink made from the insulating material is discharged or printed on a wiring path by a droplet discharge method or printing method such as ink jetting or dispensing, a pattern of stress relaxation film 18 is drawn in a line shape or band shape, and then the pattern is dried/hardened to form stress relaxation film 18.

Here, as a material for stress relaxation film 18, there are, for example, epoxy based resin, polyimide based resin, and glass based (S102) insulating materials, and it is acceptable to select a material among these insulating materials in consideration of the linear expansion coefficient, the Young's modulus, and other characteristics (for example, optical transparency, humidity resistance, adhesiveness with respect to embedded resin layer 16 and wiring 17, and so on).

Further, after stress relaxation film 18 is dried and hardened, conductive ink (ink which includes conductive particles such as Ag) is discharged or printed on stress relaxation film 18 by a droplet discharge method or printing method such as ink jetting or dispensing, a pattern of wiring 17 is drawn on stress relaxation film 18 across electrode 15 on the upper surface of LED device 14 and electrode 11a on the upper surface of package body 13, and this is dried and baked, and electrode 15 on the upper surface of LED device 14 and electrode 11a on the upper surface of package body 13 are connected with wiring 17. During this, the baking temperature of wiring 17 is around 200 degrees C. (for example 180 degrees C. or higher) and baking time is around 30 to 60 minutes.

In this case, stress relaxation film 18 is formed in a line thicker than the line width of the wiring 17 by a value appropriate for the manufacturing tolerance so that wiring 17 does not protrude from the stress relaxation film 18. Specifically, the line width of stress relaxation film 18 may be specified in a range of, for example, 1.2 to 2.5 times of the line width of wiring 17, more preferably, in a range of 1.5 to 2.0 times.

Incidentally, it is required to form wiring 17 which connects electrode 15 on the upper surface of LED device 14 and electrode 11a on the upper surface of package body 13 across multiple materials (electrode 15 on the upper surface of LED device 14, upper surface of LED device 14, embedded resin layer 16, package body 13, electrode 11a of lead frame 11, and so on) which are located on a wiring path. As given above, although large level differences (cavities) which arise in the material boundary sections in a wiring path are attempted to be filled with embedded resin layer 16, in fact, it is difficult to make level differences in the material boundary sections completely zero and tiny level differences still remain. In addition, there are tiny level differences also between electrode 15 and the upper surface of LED device 14, or between electrode 11a and the upper surface of package body 13, furthermore, there are tiny level differences also on the upper surface of LED device 14. A droplet discharge method or printing method has advantages that wiring 17 can be drawn even if there are tiny level differences in a wiring path, however, because wiring 17 is dried/baked at a specified baking temperature after drawing, wiring 17 is expanded/contracted by heating/heat dissipation during drying/baking, or wiring 17 is expanded/contracted through the temperature cycle when they are used with power being supplied after manufacturing. Due to this, with the conventional configuration previously mentioned, stresses are intensively applied to angled sections of level difference sections in the wiring by the difference in the expansion/contraction between the wiring and the land, so the wiring is sometimes disconnected at the angled sections of the level difference sections.

In contrast, in embodiment 1, because stress relaxation film 18 to reduce stresses applied to the wiring 17 due to the difference in expansion/contraction between the land and the wiring 17 is formed on a land (wiring path) which forms wiring 17, and the wiring 17 is formed on the stress relaxation film 18 by a droplet discharge method or printing method, stress applied on level difference sections of wiring 17 by the difference in expansion/contraction between the land and the wiring 17 at level difference sections can be reduced by stress relaxation film 18, and it is possible to prevent to a great extent wiring 17 formed by a droplet discharge method or printing method from being disconnected at angled sections of level difference sections by repeated expansion/contraction and the reliability of wiring 17 can be improved.

### Embodiment 2

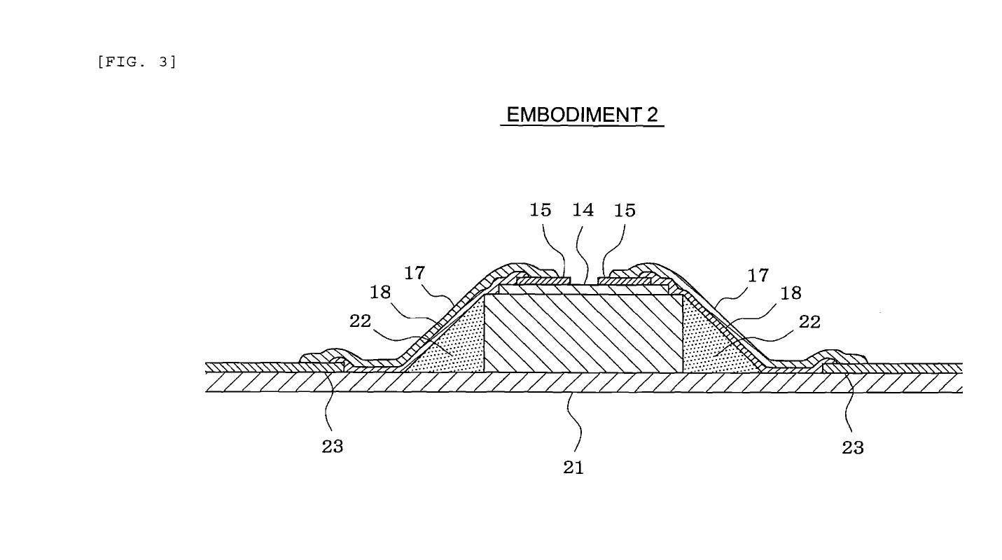

Next, embodiment 2 of the present invention is explained using FIG. 3. In this embodiment 2, LED device 14 is die bonded on wiring board 21 which is a mounting member. Around this LED device 14, by discharging liquid resin material with a dispenser, insulating resin slope 22 which connects the upper surface of LED device 14 and the upper surface of wiring board 21 at an inclined surface is formed, and on the surface of the resin slope 22, stress relaxation film 18, in the same way as embodiment 1 above, is drawn in a line shape or band shape across electrode 15 on the upper surface of LED device 14 and electrode 23 on the upper surface of wiring board 21 by a droplet discharge method or printing method.

Further, after stress relaxation film 18 is dried and hardened, conductive ink (ink which includes conductive particles such as Ag) is discharged on stress relaxation film 18 by a droplet discharge method, a pattern of wiring 17 is drawn on stress relaxation film 18 across electrode 15 on the upper surface of LED device 14 and electrode 23 on the upper surface of wiring board 21, and this is dried and baked, and electrode 15 on the upper surface of LED device 14 and electrode 23 on the upper surface of wiring board 21 are connected with wiring 17.

In embodiment 2 described above also, the same effects as the above embodiment 1 can be obtained.

### Embodiment 3

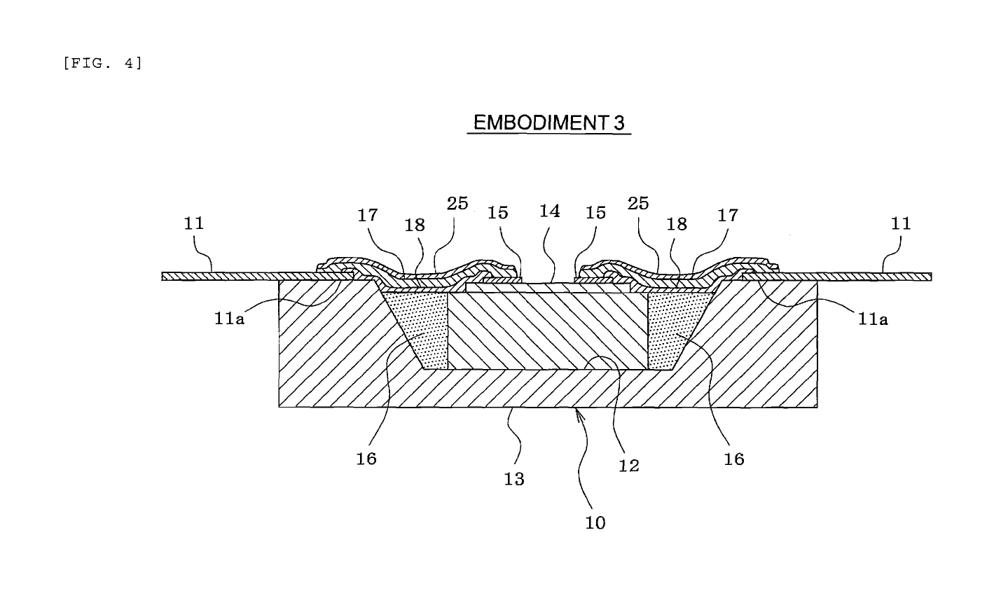

Next, embodiment 3 of the present invention is explained using FIG. 4. In this embodiment 3, for an LED package which has the structure as embodiment 1 above, stress relaxation film 25 the same as stress relaxation film 18 at the lower surface side of the wiring 17 is also formed on the upper surface of wiring 17 by a droplet discharge method or printing method, and the configuration is such that both upper and lower surfaces of the wiring 17 are sandwiched by stress relaxation films 25 and 18. Other configurations are the same as embodiment 1 above.

In this embodiment 3, because both upper and lower surfaces of wiring 17 are sandwiched by stress relaxation films 18 and 25, the stress relaxation effects on wiring 17 by stress relaxation films 18 and 25 are increased, therefore wiring 17 formed by a droplet discharge method or printing method can reliably be prevented from being disconnected at angled sections of level difference sections by repeated expansion/contraction.

Further, also for an LED package with the structure of embodiment 2 above (refer to FIG. 3), in the same way as embodiment 3 above, it is acceptable to form a stress relaxation film the same as stress relaxation film 18 at the lower surface side of the wiring 17 on the upper surface of wiring 17 by a droplet discharge method or printing method.

### Embodiment 4

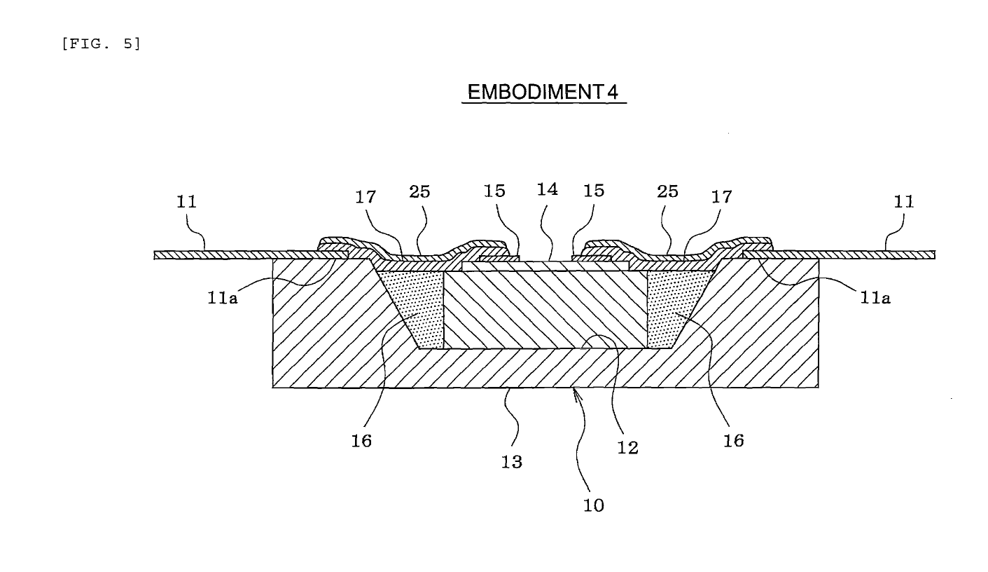

Next, embodiment 4 of the present invention is explained using FIG. 5. In this embodiment 4, for an LED package which has the structure of the embodiment 1 above, in a wiring path which connects electrode 15 on the upper surface of LED device 14 and electrode 11 a on the upper surface of package body 13, a pattern of wiring 17 is drawn by a droplet discharge method or printing method without forming stress relaxation film 18, and this is dried and baked, and electrode 15 on the upper surface of LED device 14 and electrode 11 a on the upper surface of package body 13 are connected with wiring 17. After this, on the upper surface of wiring 17, stress relaxation film 25 the same as embodiment 3 above is formed by a droplet discharge method or printing method.

In embodiment 4 described above also, because stresses applied to level difference sections in wiring 17 by difference in expansion/contraction between a land and wiring 17 at level difference sections can be reduced by stress relaxation film 25 formed on the upper surface, it is possible to prevent to a great extent wiring 17 formed by a droplet discharge method or printing method from being disconnected at angled sections of level difference sections by repeated expansion/contraction.

Further, also for an LED package with the structure of embodiment 2 above (refer to FIG. 3), in the same way as embodiment 4, it is acceptable to form wiring 17 by a droplet discharge method or printing method without forming stress relaxation film 18 in a wiring path which connects electrode 15 on the upper surface of LED device 14 and electrode 23 on the upper surface of wiring board 21, and, the same as embodiment 3 above, to form a stress relaxation film on the upper surface of the wiring 17 by a droplet discharge method or printing method.

### Embodiment 5

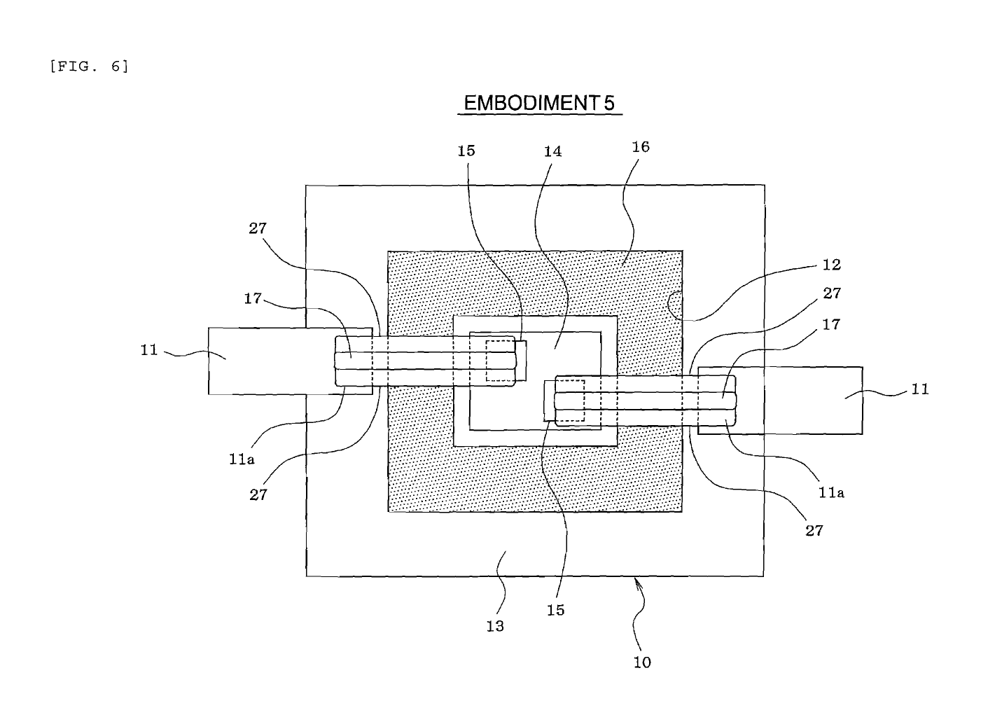

Next, embodiment 5 of the present invention is explained using FIG. 6.

In this embodiment 5, for an LED package which has the structure of the embodiment 1 above, in the same way as embodiment 4 above, in a wiring path which connects electrode 15 on the upper surface of LED device 14 and electrode 11 a on the upper surface of package body 13, wiring 17 is formed by a droplet discharge method or printing method without forming stress relaxation film 18. After this, stress relaxation film 27 the same as embodiment 3 above is formed along both side surfaces (or one side surface) of wiring 17 by a droplet discharge method or printing method.

In embodiment 5 described above also, because stresses applied to level difference sections in wiring 17 by difference in expansion/contraction between a land and wiring 17 at level difference sections can be reduced by stress relaxation film 27 formed along both side surfaces (or one side surface), it is possible to prevent to a great extent wiring 17 formed by a droplet discharge method or printing method from being disconnected at angled sections of level difference sections by repeated expansion/contraction.

Further, also for an LED package with the structure of embodiment 2 above (refer to FIG. 3), in the same way as embodiment 5, it is acceptable to form wiring 17 by a droplet discharge method or printing method without forming stress relaxation film 18 in a wiring path which connects electrode 15 on the upper surface of LED device 14 and electrode 23 on the upper surface of wiring board 21, and to form a stress relaxation film along both side surfaces (or one side surface) of the wiring 17 by a droplet discharge method or printing method.

Also, when a stress relaxation film is formed on the upper surface of wiring 17, it is also acceptable to form a stress relaxation film across the upper surface of wiring 17 and both side surfaces (or one side surface) by forming a stress relaxation film with a wide width such that the stress relaxation film exceeds the width of wiring 17. Similarly, when a stress relaxation film is formed at the lower surface side of wiring 17, it is also acceptable to form a stress relaxation film across the lower surface of wiring 17 and both side surfaces (or one side surface) by forming a stress relaxation film with a wide width such that the stress relaxation film exceeds the width of wiring at both sides (or one side). In addition, when a stress relaxation film is formed at the lower surface side of wiring 17, it is also acceptable to form a stress relaxation film on the upper surface of embedded resin layer 16 or resin slope 22 almost entirely. Furthermore, for an LED package, when a stress relaxation film is formed over a wide range, it is desirable to form the stress relaxation film with a transparent material so that the stress relaxation film does not block the light of LED device 14.

In the above embodiments 1 to 5, stress relaxation films 18, 25, 27 are formed over almost the entire length of wiring 17; however, it is also acceptable to form a stress relaxation film only at the level difference sections or form a stress relaxation film only at the level difference sections and their surrounding sections considering the fact that stresses are concentrated at level difference sections of wiring 17 due to difference in expansion/contraction between the land and the wiring 17.

Also, a method to form wiring 17 is not limited to a droplet discharge method or printing method, and it is also acceptable to form wiring 17 by any of plating, PVD, mounting conductive member, and so on.

Furthermore, a method for forming a stress relaxation film is also not limited to a droplet discharge method or printing method, and it is also acceptable to connect an insulating film or solid insulation used as a stress relaxation film to a land or wiring.

In addition, it goes without saying that the present invention is not limited to an LED package, and various embodiments with changes that do not extend beyond the scope of the invention are possible such as that it can be applied to various semiconductor packages with which semiconductor devices other than LED devices are mounted on a mounting member.

### SYMBOL DESCRIPTIONS

10: Mounting member; 11: Lead frame; 11a: Electrode; 12: Element mounting cavity; 13: Package body; 14: LED device (semiconductor device); 15: Electrode; 16: Embedded resin layer; 17: Wiring; 18: Stress relaxation film; 21: Wiring board (mounting member); 22: Resin slope; 23: Electrode; 25, 27: Stress relaxation film

1. A semiconductor package with a semiconductor device mounted on a mounting member, the semiconductor package comprising:
wiring connecting an electrode of a semiconductor side and an electrode of a mounting member side,
wherein a stress relaxation film to reduce stresses applied to the wiring due to a difference in expansion/contraction between level difference sections and the wiring is formed at least at the level difference sections among sections which form the wiring, and
wherein the wiring is formed on the stress relaxation layer.

2. A semiconductor package according to claim 1, wherein a stress relaxation film to reduce stresses applied to the wiring due to the difference in expansion/contraction between a land and the wiring at the level difference sections is formed at at least one of an upper surface or a side surface of level difference sections in the wiring.

3. A semiconductor package with a semiconductor device mounted on a mounting member, the semiconductor package comprising:
wiring connecting an electrode of a semiconductor side and an electrode of a mounting member side,
wherein a stress relaxation film to reduce stresses applied to the wiring due to a difference in expansion/contraction between a land and the wiring at the level difference sections is formed at at least one of an upper surface or a side surface of level difference sections in the wiring.

4. A semiconductor package according to claim 1, wherein the wiring is formed by any one of a droplet discharge method, printing method, plating, PVD, or mounting conductive member.

5. A semiconductor package according to claim 1, wherein the stress relaxation film is formed of a material for which a difference of a linear expansion coefficient from a linear expansion coefficient of the wiring is equal to or smaller than a predetermined value.

6. A semiconductor package according to claim 1, wherein the stress relaxation film is formed by a droplet discharge method or printing method.

7. A manufacturing method for a semiconductor package with a semiconductor device mounted on a mounting member which is formed with wiring connecting an electrode of a semiconductor side and an electrode of a mounting member side, the method comprising:
forming a stress relaxation film to reduce stresses applied to the wiring due to a difference in expansion/contraction between level difference sections at least at the level difference sections forming the wiring; and
forming the wiring on the stress relaxation layer by any one of a droplet discharge method, printing method, plating, PVD, or mounting conductive member.

8. A manufacturing method for a semiconductor package with a semiconductor device mounted on a mounting member which is formed with wiring connecting an electrode of a semiconductor side and an electrode of a mounting member side, the method comprising:
forming the wiring by any one of a droplet discharge method, printing method, plating, PVD, or mounting conductive member; and
forming a stress relaxation layer to reduce stresses applied to the wiring due to a difference in expansion/contraction between level difference sections at at least one of an upper surface or a side surface of the level difference in the wiring.
